(19) United States
(12) Patent Application Publication
(10) Pub. No.: US 2016/0268249 A1
(43) Pub. Date: Sep. 15, 2016

(54) SEMICONDUCTOR DEVICE

(71) Applicant: KABUSHIKI KAISHA TOSHIBA, Tokyo (JP)

(72) Inventor: Makoto TSUZUKI, Ibo Hyogo (JP)

(21) Appl. No.: 14/839,488

(22) Filed: Aug. 28, 2015

(30) Foreign Application Priority Data
Mar. 13, 2015 (JP) 2015-050821

(51) Int. Cl. H01L 27/02; H01L 29/04; H01L 29/66; H01L 29/866; H01L 25/00; H01L 25/16; H01L 29/16

(52) U.S. Cl. CPC H01L 27/0255; H01L 25/16; H01L 29/04; H01L 29/16; H01L 29/866; H01L 25/50; H01L 29/66106

(57) ABSTRACT

A semiconductor device includes a transistor that is connected to a load. A first diode is provided on a single crystal semiconductor layer, and is connected between a drain of the transistor and a gate of the transistor so that a current direction from the gate to the drain is a forward direction. A second diode is provided on the single crystal semiconductor layer, and is connected between the first diode and the gate of the transistor or between the first diode and the drain of the transistor so that a forward direction is opposite to the forward direction of the first diode.

### CROSS-REFERENCE TO RELATED APPLICATION

This application is based upon and claims the benefit of priority from Japanese Patent Application No. 2015-050821, filed Mar. 13, 2015, the entire contents of which are incorporated herein by reference.

### FIELD

An embodiment described herein relates generally to a semiconductor device.

### BACKGROUND

An active clamp circuit is used to protect a switch from an induced electromotive force generated by a load (inductor). When a Metal Oxide Semiconductor Field Effect Transistor (MOSFET) is used as a switch, the active clamp circuit includes a zener diode made of polysilicon that is formed on the same semiconductor chip as that on which the MOSFET is formed. However, the zener diode made of polysilicon has a relatively high resistance (clamp resistance) after breakdown and cannot apply a sufficient voltage to a gate of the MOSFET. In this case, there is a fear that the active clamp circuit may not sufficiently protect the MOSFET.

### DESCRIPTION OF THE DRAWINGS

FIG. 1 is a schematic plan view which shows an example of a configuration of a semiconductor device according to an embodiment.

FIG. 2A is are a sectional view which shows an example of a configuration of a MOSFET at section A-A of FIG. 1-, and FIG. 2B is a sectional view which shows an example of a configuration of a first zener diode at section B-B of FIG. 1.

FIG. 3 is an equivalent circuit diagram which shows an example of the configuration of the semiconductor device according to the embodiment.

FIG. 4 is a graph which shows a current-voltage characteristic of the zener diode.

FIG. 5 is a circuit diagram which shows an example of a configuration of a second semiconductor chip according to a modification example of the embodiment.

### DETAILED DESCRIPTION

In general, according to one embodiment, a semiconductor device includes a transistor that is connected to a load. A first diode is provided on a single crystal semiconductor layer, and is connected between the drain of the transistor and the gate of the transistor so that a current direction from the gate to the drain is a forward direction. A second diode is provided on the single crystal semiconductor layer, and is connected between the first diode and the gate of the transistor or between the first diode and the drain of the transistor so that the current forward direction therethrough is opposite to the forward direction of the first diode.

Hereinafter, an exemplary embodiment will be described with referring to drawings. The embodiment does not limit the invention. In the following embodiment, a vertical direction of the semiconductor device and a semiconductor package shows a relative direction when a surface of a substrate on which a semiconductor element is provided or a surface of a frame on which a semiconductor chip is provided is an upper side, and may be different from a vertical direction according to gravitational acceleration in some cases.

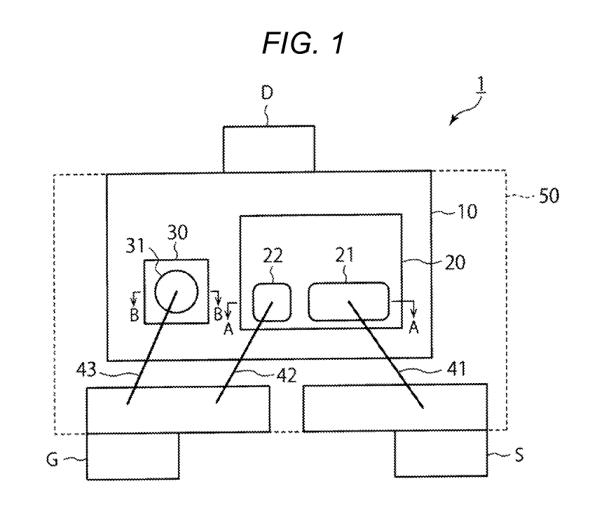

FIG. 1 is a schematic plan view which shows an example of a configuration of a semiconductor device 1 according to the embodiment. The semiconductor device 1 includes a frame 10, a first semiconductor chip 20, a second semiconductor chip 30, metal wires 41 to 43, a source terminal S, a drain terminal D, a gate terminal G, and an encapsulating sealing resin 50 (shown in phantom). The plan view shown in FIG. 1 is merely schematic, and the arrangement of the terminals and the like may be different from actual devices.

The frame 10 is provided as a bed of a lead frame on which are mounted the first semiconductor chip 20 and the second semiconductor chip 30. The frame 10 is electrically connected to a drain electrode (not shown in FIG. 1) provided on the back surfaces of the first semiconductor chip 20 and the second semiconductor chip 30, and is from there electrically connected to the drain terminal D. A metal with low resistance and high thermal conductivity such as copper, nickel-plated copper, silver-plated copper, gold-plated copper, a copper alloy, or aluminum is used for the frame 10. The drain terminal D may be integrated with the frame 10.

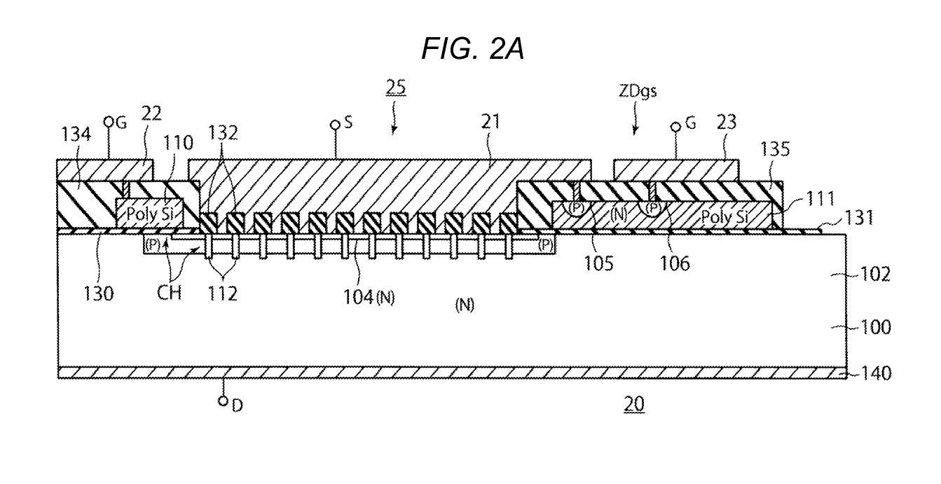

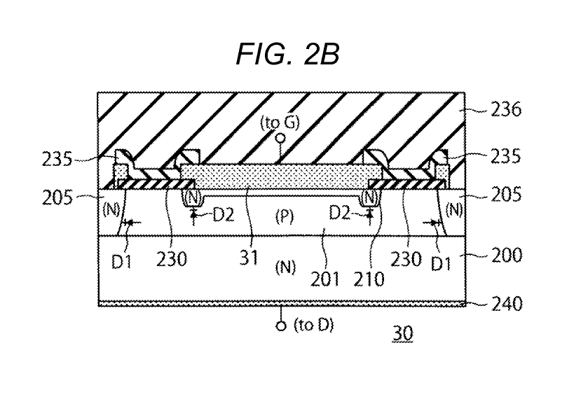

The first semiconductor chip 20 is mounted on the frame 10, and is electrically connected to the frame 10. The first semiconductor chip 20 includes a MOSFET (refer to 25 in FIG. 2A) provided on a semiconductor substrate. The source electrode 21 of the MOSFET is electrically connected to the source terminal S through the metal wire 41. The gate electrode 22 of the MOSFET is connected to the gate terminal G through the metal wire 42. The drain electrode of the MOSFET is provided on the back surface of the semiconductor substrate, and is electrically connected to the drain terminal D through the frame 10.

The MOSFET supplies power to a load when it is turned on, and blocks the power to the load when it is turned off. For example, the drain terminal D is connected to a power source through a load having an inductance, and the MOSFET is turned on when it is supplying power to the load, and is turned off when it prevents the supply of power to the load. That is, the MOSFET switches power to the load on and off.

The first semiconductor chip 20 may include a bidirectional zener diode which is connected between the gate and the source of the MOSFET externally of the MOSFET. A detailed configuration of the MOSFET and the bidirectional zener diode located between the source and the gate will be described.

The second semiconductor chip 30 is different from the first semiconductor chip 20, and includes a semiconductor substrate which is different from that of the first semiconductor chip 20. The second semiconductor chip 30 includes a first diode and a second diode which are provided on the semiconductor substrate. The first and the second diodes are commonly connected to an anode. A cathode electrode 31 of the second diode is connected to the gate terminal G through the metal wire 43. A cathode electrode (not shown in FIG. 1) of the first diode is provided on a back surface of the second semiconductor chip 30, and is connected to the drain electrode of the MOSFET and the drain terminal D. The first diode is provided between a gate and a drain of the MOSFET so that the MOSFET is not destroyed by an induced electromotive force when in an off state. The second diode is provided so as to prevent a reverse flow of a current from the gate terminal G to the drain terminal D when a control circuit applies a voltage to the gate terminal G. A detailed description of the first and the second diodes will be described.

The source terminal S and the gate terminal G are provided as connectors, and may be formed of the same material as the frame 10. The drain terminal D may be integrated with the frame 10, and may be formed of the same material as the frame 10.

The sealing resin 50 seals and protects the frame 10, the first and the second semiconductor chips 20 and 30, the source terminal S, and the drain terminal D as a single package.

FIG. 2A is a sectional view which shows an example of a configuration of the MOSFET 25 and a bidirectional zener diode ZDgs which are both provided on the first semiconductor chip 20. FIG. 2A is a sectional view taken along section A-A of FIG. 1.

The MOSFET 25 includes a semiconductor layer 100, a drain diffusion layer 102, a source diffusion layer 104, a channel region CH, a gate electrode 110, a plurality of trench gate electrodes 112, the source electrode 21, the gate electrode 22, a gate insulating film 130, interlayer insulation films 132 and 134, and a metal layer 140.

The semiconductor layer 100 is a single crystal semiconductor layer such as a single crystal silicon. The drain diffusion layer 102, the source diffusion layer 104, and the channel region CH are impurity doped diffusion layers provided on the semiconductor layer 100. For example, when the MOSFET is an n-type transistor, the drain diffusion layer 102 and the source diffusion layer 104 are diffusion layers including an n-type impurity as a dopant therein. The channel region CH is a diffusion layer including a p-type impurity as a dopant therein or is an intrinsic semiconductor layer.

The gate electrode 110 is provided over the semiconductor layer 100 of the channel region CH with the gate insulating film 130 disposed therebetween. A conductive material such as doped polysilicon is used for the gate electrode 110.

A plurality of trench gate electrodes 112 are provided between the source diffusion layer 104 and the drain diffusion layer 102 through the channel region CH of the semiconductor layer 110, respectively. The plurality of trench gate electrodes 112 are electrically insulated from the semiconductor layer 100, and are electrically connected to the gate electrode 110. A gate voltage is applied to both the gate electrode 110 and the trench gate electrodes 112. In this manner, the width of the channel CH of the MOSFET 25 becomes substantially large, and a large amount of current can flow between the source and the drain of the MOSFET 25.

The source electrode 21 is electrically connected to the source diffusion layer 104. Metals with low resistance such as copper and tungsten are used for the source electrode 21.

The gate electrode 22 is electrically connected to the polysilicon gate electrode 110 and the polysilicon trench gate electrodes 112. Metals with low resistance such as copper and tungsten are used for the gate electrode 22.

A patterned interlayer insulation film 132 is provided between each of the trench gate electrode 112 and the overlying source electrode 21, and this patterned film electrically isolate the trench gate electrodes 112 from the source electrode 21. An insulation film such as a silicon oxide film is used for the interlayer insulation film 132.

The interlayer insulation film 134 is provided between the gate electrode 110 and the source electrode 21, and it electrically isolates the gate electrode 110 from the source electrode 21. An insulation film such as a silicon oxide film is used for the interlayer insulation film 134.

The metal layer 140 is provided on the back surface of the semiconductor layer 100, and is electrically connected to the drain diffusion layer 102. That is, the metal layer 140 functions as a drain electrode. Metals with low resistance such as copper and tungsten are used for the metal layer 140.

Furthermore, the bidirectional zener diode ZDgs and the MOSFET 25 are also provided on the semiconductor layer 100. The bidirectional zener diode ZDgs is provided using a polysilicon layer 111 on an insulation film 131 formed on the semiconductor layer 100. The insulation film 131 may be formed of the same material as the gate insulating film 130 of the MOSFET 25. The polysilicon layer 111 may be formed of the same material as the gate electrode 110 of the MOSFET 25.

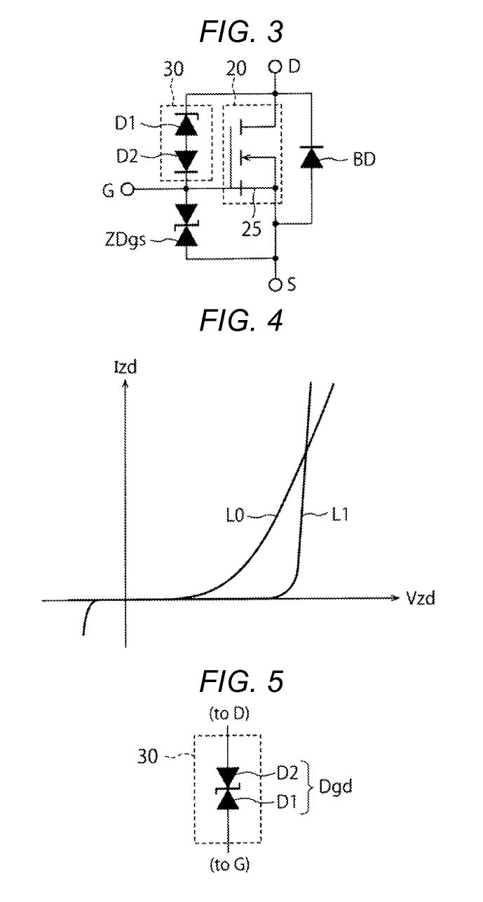

The bidirectional zener diode ZDgs is made of two zener diodes commonly connected to a cathode as described with reference to FIG. 3. An anode (p-type diffusion layer 105) of one zener diode of the bidirectional zener diode ZDgs is connected to the source electrode 21 of the MOSFET 25. An anode (p-type diffusion layer 106) of the other zener diode of the bidirectional zener diode ZDgs is connected to a gate electrode 23. The gate electrode 23 is connected to the gate terminal G in common with the gate electrode 22 of the MOSFET 25. In this manner, the MOSFET 25 and the bidirectional zener diode ZDgs are provided on the same first semiconductor chip 20. The bidirectional zener diode ZDgs may also be provided on a semiconductor chip other than the first semiconductor chip 20.

FIG. 2B is a sectional view which shows an example of a configuration of first and second diodes D1 and D2 provided on the second semiconductor chip 30. FIG. 2B is a sectional view taken along section B-B of FIG. 1.

In the embodiment, the first and the second diodes D1 and D2 form a bidirectional diode or a bidirectional zener diode which is commonly connected to an anode electrode on the second semiconductor chip 30.

The second semiconductor chip 30 includes an n-type semiconductor layer 200, a p-type epitaxial layer 201 (a single crystal semiconductor layer), an n-type diffusion layer 205, an n-type diffusion layer 210, the cathode electrode 31, insulation films 230 and 235, an interlayer insulation film 236, and a cathode electrode 240. The semiconductor layer 200 is provided on a semiconductor chip (substrate) different from the one on which the semiconductor layer 100 of FIG. 2A is provided. The semiconductor layer 200 includes an n-type impurity dopant, and is a single crystal semiconductor layer such as a silicon single crystal.

The epitaxial layer 201 is provided on the semiconductor layer 200, and includes a p-type impurity. The epitaxial layer 201 is not a polysilicon layer, but is a single crystal semiconductor layer of, for example, single crystal silicon.

The n-type diffusion layer 210 extends inwardly of a surface region of the epitaxial layer 201, and is a semiconductor layer containing an n-type impurity as a dopant. The n-type diffusion layer 210 is a diffusion layer on a cathode side of the second diode D2, in the embodiment, it contacts the cathode electrode 31. The second diode D2 is formed by the n-type diffusion layer 210 and the p-type epitaxial layer 201. The second diode D2 may be a zener diode, or may be a normal diode with higher avalanche breakdown voltage than a zener diode.

The n-type diffusion layer 205 surrounds the p-type epitaxial layer 201, and is a semiconductor layer containing an n-type impurity as a dopant thereof. The diffusion layer 205 is electrically connected to the semiconductor layer 200. The first diode D1 is formed between the n-type diffusion layer 205 and the p-type epitaxial layer 201. The first diode D1 may be a zener diode, and may be a normal diode with higher avalanche breakdown voltage than a zener diode. In the embodiment, the first and the second diodes D1 and D2 are together configured as a bidirectional diode or a bidirectional zener diode with a common anode. In this manner, as described later, the first and the second diodes may function as an active clamp circuit that protects the MOSFET 25.

The cathode electrode 31 of the second diode D2 is electrically connected to the n-type diffusion layer 210. The cathode electrode 31 is electrically connected to the gate terminal G through the metal wire 43 as shown in FIG. 1.

The insulation films 230 and 235 are provided and surround the cathode electrode 31, and electrically insulate the cathode electrode 31 from the n-type diffusion layer 205.

The interlayer insulation film 236 is provided on the cathode electrode 31, the insulation film 235 and the like. An insulation film such as a silicon oxide film is used for the interlayer insulation film 236.

The cathode electrode 240 is provided on a back surface of the semiconductor layer 200, and is electrically connected to the semiconductor layer 200. Metals with low electrical resistance such as copper and tungsten are used for the cathode electrode 240. The cathode electrode 240 functions as a cathode electrode of the first diode D1. The cathode electrode 240 is electrically connected to the drain terminal D through the frame 10 as shown in FIG. 1.

In this manner, in the embodiment, a MOSFET 25 which switches power and an active clamp circuit (the first and the second diodes D1 and D2) which protects the MOSFET 25 are provided on different individual semiconductor chips (20 or 30). The active clamp circuit is provided on a chip different from that of the MOSFET 25, and thus the first and the second diodes D1 and D2 (forming the bidirectional diode or bidirectional zener diode) may be provided using a single crystal semiconductor layer 200 or 201 such as a silicon single crystal layer, rather than using a polysilicon layer.

FIG. 3 is an equivalent circuit diagram which shows an example of a configuration of the semiconductor device 1 according to the embodiment. The MOSFET 25 provided on the first semiconductor chip 20 is controlled to be turned on or off by a voltage applied to the gate terminal G, which allows current to flow between the source terminal S and the drain terminal D when the device is in the on state. The drain terminal D at an end of the MOSFET 25 is connected to a load (not shown). The gate terminal G is connected to, for example, a controller (not shown). The controller applies a voltage to the gate terminal G so as to cause the MOSFET 25 to perform an on/off switching operation.

The cathode of the first diode D1 provided on the second semiconductor chip 30 is connected between the drain terminal D and the gate terminal G. The anode of the first diode D1 is connected to the gate terminal G through the second diode D2, and the cathode of the first diode D1 is connected to the drain terminal D. That is, the first diode D1 is connected between the drain terminal D of the MOSFET 25 and the gate terminal G of the MOSFET 25 so that the direction from the gate terminal G to the drain terminal D is the forward current flow direction, and so that the direction from the drain terminal D to the gate terminal G is the reverse current flow direction of diode D1. The first diode D1 in FIG. 3 is a zener diode.

In addition, the anode of the second diode D2 is connected in common with the anode of the first diode D1, and the cathode of the second diode D2 is connected to the gate terminal G. That is, the second diode D2 is connected between the first diode D1 and the gate terminal G so that a forward direction of current flow of the second diode D1 is opposite to a forward direction of current flow of the first diode D1. The second diode D2 is provided to prevent a reverse flow of current from the gate terminal G to the drain terminal D. In FIG. 3, the second diode D2 is a general diode with higher breakdown voltage (avalanche resistance) than the first diode D1.

Furthermore, the bidirectional zener diode ZDgs is connected between the gate terminal G and the source terminal S. The bidirectional zener diode ZDgs is provided to protect the MOSFET 25 from electro-static discharge (ESD). The bidirectional zener diode ZDgs may be provided on the same first semiconductor chip 20 on which the MOSFET 25 is formed, may be provided on the second semiconductor chip 30, and moreover, may be provided on a semiconductor chip (not shown) different from the first and the second semiconductor chips 20 and 30. A body diode BD is parasitically formed between the drain terminal D and the source terminal S. The body diode BD is provided on the same first semiconductor chip 20 on which the MOSFET 25 is formed.

The first diode D1 is, for example, a zener diode which experiences breakdown when a predetermined reverse direction bias is applied thereto. Accordingly, if a voltage equal to or more than a breakdown voltage is applied to the drain terminal D when the MOSFET 25 is in an off state, the first diode D1 clamps a voltage on a cathode side (drain voltage) up to a breakdown voltage. As described later with reference to FIG. 4, the first diode D1 is provided on the semiconductor layer 200 of single crystal, whereby the first diode D1 may more reliably protect the MOSFET 25 from a surge voltage due to an induced voltage from the load or electro-static discharge (ESD) from a load. In addition, the second diode D2 is connected between the first diode D1 and the gate of the MOSFET 25 so that its forward direction is opposite to the forward direction of the first diode D1. Accordingly, the second diode D2 prevents against reverse flow of current from the gate terminal G to the drain terminal D when a gate voltage is applied to the gate terminal G.

Next, an operation of the semiconductor device 1 according to the embodiment will be described.

When the MOSFET 25 is switched to the off state from an on state, an induced voltage is generated from a load (inductor). When the induced voltage exceeds a breakdown voltage (zener voltage when the first diode D1 is a zener diode) of the first diode D1, the first diode D1 experiences break down (avalanche breakdown), and the voltage at the gate terminal G thus increases. By an increase in the gate voltage, the MOSFET 25 is turned on, and it is possible to allow the induced current from the load to flow from the drain terminal D to the source terminal S. In this manner, the first diode D1 protects the MOSFET 25 from the induced voltage from the load.

Here, in the embodiment, the first diode D1 which functions as an active clamp circuit is connected between the drain and the gate of the MOSFET, and is provided on the second semiconductor chip 30 which is different from the first semiconductor chip 20 on which the MOSFET 25 is formed. Accordingly, the first diode D1 may be formed not on a polysilicon layer, but on a single crystal semiconductor layer such as a silicon single crystal layer. Accordingly, as shown in FIG. 4, the first diode D1 has steep current-voltage characteristics once breakdown voltage is present in the backwards flow direction thereof.

FIG. 4 is a graph which shows current-voltage characteristics of a diode. A vertical axis shows a current Izd in a reverse direction which flows in the diode, and a horizontal axis shows a voltage Vzd in the reverse direction which is applied to the diode. Hereinafter, the first diode D1 is described as a zener diode.

The line L0 shows the current-voltage characteristics of a zener diode formed on a polysilicon layer (hereinafter, referred to as polysilicon zener diode), and the line L1 shows the current-voltage characteristics of the first diode D1 according to the embodiment which is formed on or of a silicon single crystal layer.

As shown by the line L0, when the voltage Vzd in a reverse direction is increased on the polysilicon zener diode, the current Izd is gradually increased once a threshold voltage value is reached. In contrast, as shown in the line L1, when the voltage Vzd in a reverse direction is increased on the first diode D1 formed on the silicon single crystal layer, the current Izd steeply increases when a threshold voltage is reached. Accordingly, the first diode D1 has higher breakdown voltage (avalanche resistance) and lower resistance (clamping resistance or dynamic resistance) after breakdown than the polysilicon zener diode. The characteristics also applies to a normal diode which has higher avalanche breakdown voltage than the zener diode.

When the MOSFET 25 is in an off state, for example, a load dump surge voltage or the like can be applied to the drain terminal Din some cases. When this occurs, the MOSFET 25 needs to maintain the off state, but when a breakdown voltage of a clamp circuit is too low, there is a fear that the clamp circuit incorrectly operates and the MOSFET 25 is turned on because the load dump voltage is sufficient to energize the gate to the on state once the breakdown voltage of the diode is reached. In contrast, since the first diode D1 according to the embodiment has a relatively high breakdown voltage (avalanche resistance), it is possible to suppress the occurrence of a MOSFET 25 which is in an off state being switched on or activated. In addition, the avalanche resistance of the first diode D1 is high, and thereby a supply voltage of the MOSFET may be also set to be high.

Moreover, the clamp circuit needs to transmit a drain voltage to the gate terminal G with sufficiently low resistance when clamping the induced voltage from the load. When resistance (dynamic resistance) at a time of clamping of the clamp circuit is too low, a voltage of the gate terminal G is not sufficiently increased, and an on-resistance of the MOSFET 25 is not sufficiently decreased. In this case, there is a fear that the MOSFET 25 is destroyed by the induced voltage from the load at the drain terminal D. Here, the clamp circuit cannot sufficiently protect the MOSFET 25. In contrast, the first diode D1 according to the embodiment has sufficiently low clamp resistance or dynamic resistance, it is possible to sufficiently lower the on-resistance of the MOSFET 25. As a result, the first diode D1 may more reliably protect the MOSFET 25 from the induced voltage from a load or from a surge voltage due to an ESD.

### Modification Example

FIG. 5 is a circuit diagram which shows an example of a configuration of the second semiconductor chip 30 according to a modification example of the embodiment. In the modification example, the second semiconductor chip 30 includes a bidirectional diode Dgd. The bidirectional diode Dgd is connected in series between a drain and a gate of the MOSFET 25, and includes two diodes D1 and D2 to which a cathode is commonly connected. The first and the second diodes D1 and D2 are, for example, zener diodes. In this case, the bidirectional diode Dgd is a bidirectional zener diode.

In the sectional structure of the bidirectional diode Dgd according to the modification example, the impurity or dopant conductivity type of the semiconductor layers 200 and 201 and the diffusion layers 205 and 210 are reversed from that shown in the sectional structure shown in FIG. 2B.

An anode of the first diode D1 is connected to the gate terminal G. An anode of the second diode D2 is connected to the drain terminal D. In the modification example, the second diode D2 is connected between the first diode D1 and the drain terminal D of the MOSFET 25 so that a forward direction of current flow therethrough is opposite to the forward direction of the current flow of the first diode D1. Accordingly, the second diode D2 prevents a reverse flow of current from the gate terminal G to the drain terminal D.

The bidirectional diode Dgd is connected between the drain and the gate in the same manner as the first diode D1, and is provided on the second semiconductor chip 30 different from the first semiconductor chip 20 on which the MOSFET 25 is formed. In addition, the bidirectional diode Dgd is formed on or of a single crystal semiconductor layer such as a silicon single crystal layer in the same manner as the first diode D1. In this manner, the bidirectional diode Dgd according to the modification example has a higher breakdown voltage (avalanche resistance) and lower resistance (dynamic resistance) at a time of clamping after breakdown than the polysilicon diode. As a result, the semiconductor device 1 according to the modification example may reliably protect the MOSFET 25 from the induced voltage or the surge (ESD) voltage in the same manner as the embodiment described above.

In the embodiment described above, the MOSFET 25 is an n-type MOSFET. However, the MOSFET 25 may be a p-type MOSFET. In this case, when the induced voltage from the load lowers the voltage of the drain terminal D, the first or the second diode D1 or D2 experiences breakdown which causes the MOSFET 25 to be switched to the on state. Accordingly, the first or the second diode D1 or D2 may protect the MOSFET 25 from the induced voltage as a clamp circuit.

In addition, in the embodiment described above, the load is provided on a drain terminal D side. However, the load may be provided on a source terminal S side. Even in this case, an induced voltage force from a power supply may be applied to the drain terminal D. Therefore, even if the load is connected to the source terminal S, an effect of the embodiment described above is not lost.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a transistor configured for connection to a load;
a first diode on a single crystal semiconductor layer, and connected between a drain of the transistor and a gate of the transistor so that a current direction from the gate to the drain is a forward direction of the first diode; and
a second diode on the single crystal semiconductor layer, and connected between one of:
the first diode and the gate of the transistor, and
the first diode and the drain of the transistor,
so that a forward current direction of the second diode is opposite to the forward current direction of the first diode.

2. The device according to claim 1, wherein
the transistor is on a first semiconductor chip, and
the first diode is on a second semiconductor chip that is different from the first semiconductor chip.

3. The device according to claim 2, wherein
the first semiconductor chip and the second semiconductor chip are parts of a single semiconductor package.

4. The device according to claim 1, wherein
the first diode becomes conductive when an absolute value of a voltage at the drain of the transistor exceeds a predetermined value.

5. The device according to claim 1, wherein
the first diode and the second diode are bidirectional zener diodes.

6. The device according to claim 1, further comprising:
a bidirectional zener diode electrically connected in series between the gate and the source of the transistor.

7. The device of claim 6, wherein the bidirectional zener diode and the transistor are on a first semiconductor chip, and
the first diode is on a second semiconductor chip that is different from the first semiconductor chip.

8. The device of claim 7, wherein the bidirectional zener diode is formed of p-n junctions in a polysilicon layer.

9. The device of claim 8, wherein the first diode is formed of a p-n junction in a crystalline semiconductor layer.

10. A method of protecting a transistor from an overvoltage at the drain side thereof, comprising:
providing a first diode formed as a junction in a first semiconductor layer different from the semiconductor layer of the transistor, and connecting the first diode between a drain of the transistor and a gate of the transistor so that a current direction from the gate to the drain is a forward direction of the first diode; and
connecting a second diode, formed as a junction of the first semiconductor layer different from the semiconductor layer of the transistor, between one of:
the first diode and the gate of the transistor, and
the first diode and the drain of the transistor,
so that a forward current direction thereof is opposite to the forward direction of the first diode.

11. The method of claim 10, further comprising:
forming the first diode and the second diode in a single crystal semiconductor layer.

12. The method of claim 11, further comprising:
providing the transistor on a first substrate; and
providing at least one of the first diode and the second diode on a second substrate.

13. The method of claim 12, wherein the first and second diodes are formed on the same substrate.

14. The method of claim 10, further comprising:
providing a bidirectional diode between the gate and the source of the transistor.

15. The method of claim 14, further comprising:
forming the bidirectional diode as a bidirectional zener diode on the same substrate as the transistor.

16. A semiconductor device connectable to a power source and a load, comprising:
a MOSFET comprising a source connected to the power source, a drain connected to the load, and a gate; and
a first bidirectional diode structure comprising first and second diodes commonly connected to one of an anode or cathode thereof, the bidirectional diode connected between the gate and drain of the transistor,
wherein one of the first and second diodes having a forward current direction in the gate to source direction is a zener diode formed of single crystal silicon.

17. The semiconductor device of claim 16, wherein the first and second diodes of the bidirectional diode are formed of single crystal silicon.

18. The semiconductor device of claim 16, wherein the MOSFET and the bidirectional diode are provided on different semiconductor chips.

19. The semiconductor device of claim 17, further comprising:
a second bidirectional diode electrically connected between the source and the gate of the MOSFET.

20. The semiconductor device of claim 19, wherein the MOSFET and the second bidirectional diode are formed on the same semiconductor chip.
